(19) United States
(12) Patent Application Publication
(10) Pub. No.: US 2012/0138144 A1
(43) Pub. Date: Jun. 7, 2012

(54) SOLAR CELL MODULE AND SOLAR POWER GENERATING APPARATUS

(75) Inventor: Tsuyoshi Maeda, Osaka (JP)

(73) Assignee: SHARP KABUSHIKI KAISHA, Osaka (JP)

(21) Appl. No.: 13/390,211

(22) PCT Filed: Sep. 6, 2010
(86) PCT No.: PCT/JP2010/065245

§ 371 Date: Feb. 13, 2012

(30) Foreign Application Priority Data
Nov. 18, 2009 (JP) 2009-263023

(51) Int. Cl. H01L 31/0232

(52) U.S. Cl. 136/257

(57) ABSTRACT

The present invention provides a solar cell module which has a higher degree of freedom for design and can be easily manufactured at lower cost. The solar cell module (10) includes a light guide plate (1); at least one adhesive layer (4) provided on respective at least one surface of the light guide plate (1); and a solar cell element (3) which is provided on another surface perpendicular to the at least one surface. The solar cell module (10) further includes at least one light-transmitting film (2) adhered to the light guide plate (1) via the respective at least one adhesive layer (4) in which a fluorescent substance is dispersed. Therefore, it is not necessary to prepare a light guide plate in which a fluorescent substance is dispersed. Moreover, the adhesive layer(s) (4) can be freely patterned and/or stacked.

### TECHNICAL FIELD

The present invention relates to a solar cell module and a solar photovoltaic device including the solar cell module.

### BACKGROUND ART

According to a conventional solar photovoltaic device, which has been used so as to efficiently utilize solar energy, solar panels are generally spread all over a plane facing the sun. Such solar panels are each configured, in general, with the use of an opaque semiconductor. Therefore, such solar panels cannot be stacked when the solar panels are used. On this account, it is necessary to employ large solar panels in order to sufficiently collect sunlight, and accordingly, an installation area of the solar panels becomes larger. Patent Literature 1 discloses, as an example of such a solar photovoltaic device, a technique in which a fluorescent material film is provided on a light-receiving surface of a solar cell module so as to increase energy efficiency of incoming sunlight.

Patent Literature 2 discloses a technique to efficiently utilize solar energy while achieving a reduction of an area of a solar panel. In the technique disclosed in Patent Literature 2, (i) a solar cell is adhered to a side face, which is perpendicular to a daylight surface, of a light absorbing/emitting plate in which a fluorescent substance is dispersed, and (ii) the light absorbing/emitting plate is used as a windowpane of a building. According to the configuration, sunlight, which has entered through the daylight surface, is guided in the light absorbing/emitting plate, and is then converged onto the solar cell.

Patent Literature 3 discloses a technique to efficiently recover solar energy. According to the technique, a solar energy recovering window, in which a solar cell is provided on an edge part of a glass substrate on which a silicon dioxide thin film containing fluorescence is deposited by a liquid phase deposition, is used in a building, an automobile, or the like.

### CITATION LIST

### Patent Literature

### Patent Literature 1

Japanese Patent Application Publication Tokukai No. 2001-7377 A (Publication date: Jan. 12, 2001)

### Patent Literature 2

Japanese Unexamined Utility Model Application Publication Jitsukaisho No. 61-136559 (Publication date: Aug. 25, 1986)

### Patent Literature 3

Japanese Patent Application Publication Tokukaihei No. 3-273686 A (Publication date: Dec. 4, 1991)

### SUMMARY OF INVENTION

### Technical Problem

According to the technique disclosed in Patent Literature 2, it is not necessary to enlarge an area of the solar panel so as to collect sunlight, unlike the technique disclosed in Patent Literature 1. However, the manufacturing cost will be increased because a large number of plate materials containing fluorescent substances are used. Moreover, in a case where the entered light is repeatedly subjected to total reflection in the light absorbing/emitting plate, the light is to repeatedly contact with the fluorescent substance, and therefore the efficiency is declined. According to the technique disclosed in Patent Literature 3, the silicon dioxide thin film containing fluorescence is deposited on the surface of the glass substrate by the liquid phase deposition. This leads to a lower degree of freedom for design, and, in a case where the film is to be repaired for a defect or is to be altered, the entire glass substrate needs to be replaced with another one.

Under the circumstances, it is demanded to develop a solar cell module which (i) achieves space saving, (ii) can be easily manufactured at lower cost, and (iii) has a higher degree of freedom for design.

The present invention is accomplished in view of the problems, and its object is to provide (i) a solar cell module which has a higher degree of freedom for design and can be easily manufactured at low cost, and (ii) a solar photovoltaic device including the solar cell module.

### Solution to Problem

In order to attain the object, a solar cell module of the present invention includes: at least one light guide plate; at least one adhesive layer in each of which a fluorescent substance is dispersed, the at least one adhesive layer being provided on respective at least one surface of the at least one light guide plate; and a solar cell element which is provided on another surface of the at least one light guide plate, the another surface being perpendicular to the at least one surface. A solar photovoltaic device of the present invention includes the solar cell module of the present invention.

According to the configuration, the fluorescent substance is dispersed in the at least one adhesive layer, and the at least one adhesive layer, in which the fluorescent substance is dispersed, is adhered to the at least one light guide plate. It is therefore unnecessary to prepare a light guide plate in which a fluorescent substance is dispersed. Moreover, the at least one adhesive layer can be arbitrarily patterned and/or the adhesive layers can be stacked. Since the solar cell element is provided on the surface of the at least one light guide plate which surface is perpendicular to the daylight surface, it is possible to obtain sufficient power generation efficiency while configuring the solar cell module to have a small area.

As such, it is possible to provide the solar cell module which (i) achieves sufficient power generation efficiency, (ii) has a higher degree of freedom for design, and (iii) can be easily manufactured at low cost. The solar photovoltaic device including the solar cell module, accordingly, can be suitably used as a solar photovoltaic system provided at a window of a building or of an automobile or provided on a roof of a building.

### Advantageous Effects of Invention

The solar cell module of the present invention includes: at least one light guide plate; at least one adhesive layer in each of which a fluorescent substance is dispersed, the at least one adhesive layer being provided on respective at least one surface of the at least one light guide plate; and a solar cell element which is provided on another surface of the at least one light guide plate, the another surface being perpendicular to the at least one surface. The solar cell module, therefore, (i) has a higher degree of freedom for design and (ii) can be easily manufactured at low cost.

### BRIEF DESCRIPTION OF DRAWINGS

FIG. 1 is a perspective view illustrating a solar cell module in accordance with an embodiment of the present invention.

FIG. 2 is a cross-sectional view illustrating a solar cell module in accordance with an embodiment of the present invention.

FIG. 3 is a view for explaining how light is guided in a solar cell module in accordance with an embodiment of the present invention.

FIG. 4 is a cross-sectional view illustrating a solar cell module in accordance with another embodiment of the present invention.

FIG. 5 is a cross-sectional view illustrating a solar cell module in accordance with another embodiment of the present invention.

FIG. 6 is a graph illustrating a sensitivity distribution of a solar cell and a solar energy distribution.

FIG. 7 is a graph illustrating a relation between (i) a fluorescence spectrum of a solar cell module and (ii) a sensitivity distribution of a solar cell and a solar energy distribution, in accordance with an embodiment of the present invention.

FIG. 8 is a graph illustrating a relation between (i) a fluorescence spectrum of a solar cell module and (ii) a sensitivity distribution of a solar cell and a solar energy distribution, in accordance with an embodiment of the present invention.

FIG. 9 is a perspective view illustrating a solar cell module in accordance with another embodiment of the present invention.

### DESCRIPTION OF EMBODIMENTS

### Embodiment 1

### Solar Cell Module 10

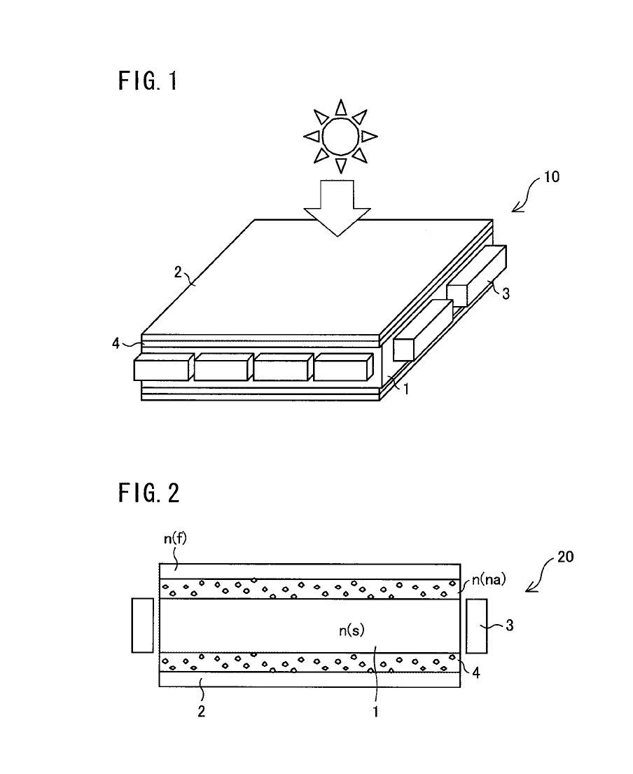

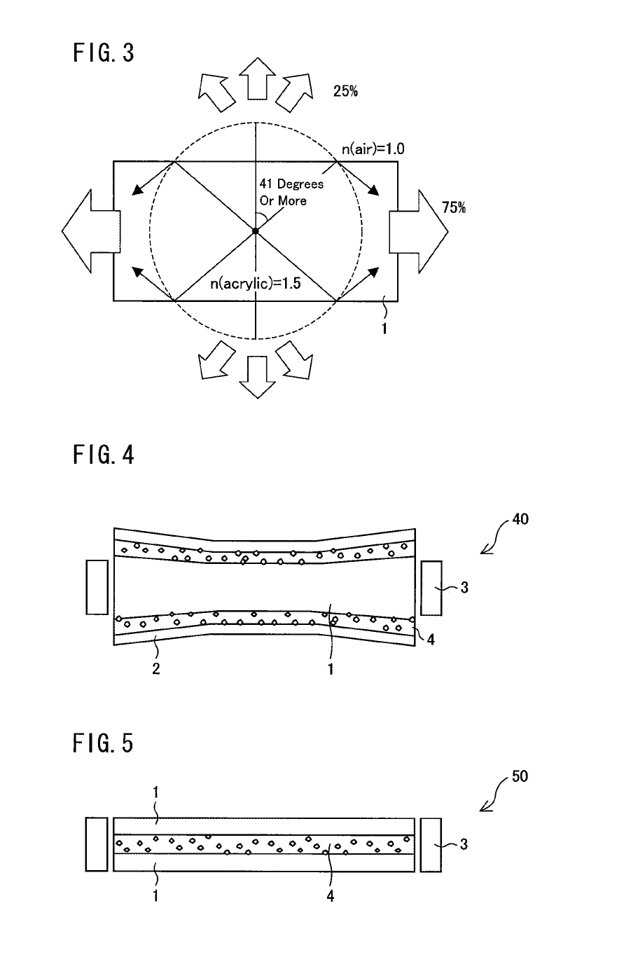

The following describes a solar cell module in accordance with an embodiment of the present invention, with reference to FIGS. 1 through 3. FIG. 1 is a perspective view illustrating a solar cell module 10. FIG. 2 is a cross-sectional view illustrating the solar cell module 10. FIG. 3 is a view for explaining how light is guided in the solar cell module 10.

The solar cell module 10 includes a light guide plate 1, an adhesive layer 4 in which a fluorescent substance is dispersed, solar cell elements 3, and a light-transmitting film 2 which is adhered to the light guide plate 1 via the adhesive layer 4 (see FIGS. 1 and 2). According to the light guide plate 1, the light-transmitting film 2 is adhered, via the adhesive layer 4, to an entire daylight surface which sunlight enters. According to the present embodiment, another light-transmitting film 2 is similarly adhered, via an adhesive layer 4, to another surface which faces the daylight surface. It follows that the solar cell module 10 of the present embodiment is configured such that the light guide plate 1 is sandwiched between the two light-transmitting films 2 which are adhered to the light guide plate 1 via the respective adhesive layers 4.

Alternatively, a light-transmitting film 2 can be merely adhered to the daylight surface via an adhesive layer 4. Note, however, that it is preferable to adhere the two light-transmitting films 2 on the entire daylight surface and the entire surface facing the daylight surface. This is because sunlight conversion efficiency is improved. According to the light guide plate 1, the solar cell elements 3 are provided on surfaces (edge surfaces) perpendicular to the daylight surface. In the present embodiment, a plurality of solar cell elements 3 are provided on each of four edge surfaces of the light guide plate 1 which edge surfaces are perpendicular to the daylight surface.

### (Light Guide Plate 1)

The light guide plate 1 is not limited to a particular light guide plate, provided that such a light guide plate diffuses light, which has entered through its daylight surface, so as to converge the light onto the solar cell elements 3 provided on its edge surfaces. A conventionally known substrate, such as an acrylic substrate, a glass substrate, or a polycarbonate substrate, can be used as the light guide plate 1. Note, however, that the present embodiment is not limited to these. A thickness of the light guide plate 1 is not limited to a particular thickness. It is preferable that the thickness of the light guide plate 1 is equal to or greater than a wavelength of visible light, i.e., 1 μm or more. It is preferable that the thickness of the light guide plate 1 is 10 cm or less, by taking into consideration (i) weight of the light guide plate 1 and (ii) an area of a part on the edge surface with which part a solar cell comes into contact.

The light guide plate 1 guides, in its inside, light which has entered the light guide plate 1. The light guide plate 1 is preferably a transparent plate which does not contain a fluorescent substance. Note, however, that the present embodiment is not limited to this, provided that the light guide plate 1 has been manufactured without being subjected to a dispersion process in which a material such as a fluorescent substance is dispersed in the light guide plate 1 so that a wavelength conversion is made in the light guide plate 1. In other words, it is possible to suitably use even a light guide plate 1, which (i) is not aimed at making a wavelength conversion, (ii) partially contains a fluorescent substance, and (iii) is not completely transparent.

In a case where the solar cell module 10 is used by being provided in a window frame of a building, the light guide plate 1 is configured by a substrate such as an acrylic substrate which has a size and a thickness allowing the light guide plate 1 to be provided in a window frame and to serve as a windowpane. Alternatively, in a case where the solar cell module is used by being provided on a roof, a size and a thickness of the light guide plate 1 can be set as appropriate, in accordance with conditions such as an installation area.

### (Adhesive Layer 4)

The adhesive layer 4 is prepared by dispersing a fluorescent substance in a light-transmitting adhesive agent. The adhesive layer 4 converts a wavelength of light, which has entered the adhesive layer 4, into a wavelength so as to obtain a wavelength range effective in making a photoelectric conversion in the solar cell element 3. The adhesive layer 4 can be prepared by using a conventionally known adhesive agent. Such an adhesive layer 4 can be prepared by dispersing a fluorescent substance in a conventionally known acrylic adhesive agent. Note that the adhesive layer 4 is not limited to this. It is therefore possible to prepare the adhesive layer 4 by dispersing a fluorescent substance in an adhesive agent such as an α-olefinic adhesive agent, an urethane resin adhesive agent, an epoxy resin adhesive agent, an ethylene-vinyl acetate resin adhesive agent, or a silicon adhesive agent.

Various kinds of fluorescent substances can be dispersed in the adhesive layer 4. It is possible to use, as the fluorescent substances, a rare earth complex such as a [Tb(bpy)2]Cl3 complex; a [Tb(terpy)2]Cl3 complex; an [Eu(phen)2]Cl3 complex; or a sialon fluorescent substance such as Ca-α-SiAlON:Eu. Note, however, that the fluorescent substances are not limited to these. Moreover, examples of the fluorescent substance, which is to be dispersed in the adhesive layer 4, encompass a hydrochloride and a sulfate of a rare earth metal such as samarium, terbium, europium, gadolinium, or dysprosium; transition metalate such as calcium molybdate or calcium tungstate; aromatic hydrocarbon such as benzene or naphthalene; or phthalein dye such as eosin or fluorescein.

It is preferable that the fluorescent substance, which is dispersed in the adhesive layer 4, has a particle diameter of 5 μm to 10 μm. This allows an efficient fluorescence emission. Moreover, it is preferable that a content of the fluorescent substance dispersed in the adhesive layer 4 is 10% by weight or less. This allows (i) a suppression of multiple scattering of light caused by the fluorescent substance and (ii) a suppression of optical quenching caused when light is absorbed by the fluorescent substance. It is therefore possible to obtain an efficient fluorescence emission.

The adhesive layer 4 can be formed as follows: that is, the adhesive agent, in which the fluorescent substance is dispersed, is applied to the light guide plate 1 or the light-transmitting film 2 so as to be stratified, and then the light-transmitting film 2 is adhered to the light guide plate 1 via the adhesive agent (i.e., an adhesive layer 4). It is preferable that the adhesive layer 4 has a thickness of 10 μm to 1000 μm, more preferably, 20 μm to 100 μm. This allows air bubbles to be prevented from getting mixed when the light-transmitting film 2 is adhered to the light guide plate 1.

### (Light-Transmitting Film 2)

A conventionally known light-transmitting film can be used as the light-transmitting film 2, provided that it allows entered light to pass through. It is possible to use, as the light-transmitting film 2, a film made of a resin such as an acrylic resin, a polypropylene resin, a cycloolefin resin, a polycarbonate resin, a triacetylcellulose resin, or a PET resin. Note that the present embodiment is not limited to these.

It is preferable that the light-transmitting film 2 has a thickness of 1 μm to 3000 μm, more preferably, 100 μm to 1000 μm. Such a thickness is suitable for providing the light-transmitting film 2 on the light guide plate 1, and the light-transmitting film 2 can therefore be easily adhered to the light guide plate 1.

According to the solar cell module 10, the adhesive layer 4 and the light guide plate 1 are configured so as to satisfy a relation n(a) n(s), where “n(a)” is a refractive index of the adhesive layer 4 and “n(s)” is a refractive index of the light guide plate 1. It is more preferable that the light guide plate 1 and the adhesive layer 4 are configured so as to satisfy a relation n(a)<n(s). With the configuration, light, which has entered the solar cell module 1, can be efficiently guided in the light guide plate 1 without being subjected to total reflection at an interface between the adhesive layer 4 and the light guide plate 1. This allows sunlight, which has entered the solar cell module 10, to be efficiently converged onto the solar cell elements 3.

The light guide plate 1, the adhesive layer 4, and the light-transmitting film 2 can be configured so as to satisfy relations n(a) n(f) and n(a)≦n(s), where “n(s)” is the refractive index of the light guide plate 1, “n(a)” is the refractive index of the adhesive layer 4, and “n(f)” is a refractive index of the light-transmitting film 2. This causes a suppression of sunlight, which has entered the light-transmitting film 2, from being reflected from an interface between the adhesive layer 4 and the light-transmitting film 2. As such, it is possible that the sunlight, which has entered the solar cell module 10, can be efficiently guided in the light guide plate 1 so as to be converged onto the solar cell elements 3.

A known solar cell, such as an amorphous silicon (a-Si) solar cell, a polycrystalline silicon solar cell, or a single crystal silicon solar cell, can be used as the solar cell element 3. However, the solar cell element 3 is not limited to these. According to the light guide plate 1, the solar cell element 3 is attached to the edge surface perpendicular to the daylight surface, via a conventionally known material or member such as a light-transmitting adhesive agent or a holding member. A size of the solar cell element 3 is not limited to a particular size. Note, however, that a light-receiving part of the solar cell element 3 preferably has a width which is identical with the thickness of the light guide plate 1. With the configuration, the solar cell elements 3 can efficiently receive light which has been guided in the light guide plate 1 and arrived at the edge surfaces of the light guide plate 1.

The following describes how the sunlight, which has entered the solar cell module 10, is guided in the light guide plate 1. When light enters a region having a lower refractive index from a region having a higher refractive index, a total reflection phenomenon is caused depending on an entry angle of the light. In a case where first light emitted from the fluorescent substance enters the light guide plate (acrylic substrate) 1, which has, for example, a refractive index of 1.5, at an entry angle between 0 degree to approximately 41 degrees with respect to the surface (whose normal direction is 0 degree) of the light guide plate 1, the first light will be directed outside of the light guide plate 1 without being subjected to total reflection in the light guide plate 1 (see FIG. 3). On the other hand, second light, which has entered the light guide plate 1 at an angle of approximately 41 degrees or more, is guided in the light guide plate 1 while being repeatedly subjected to total reflection. As compared to the first light, a ratio of the second light is approximately 75%, even in the case where the light guide plate 1 is made of the acrylic substrate having the refractive index of 1.5.

Here, a solar cell module 10 having a configuration illustrated in FIGS. 1 and 2 was prepared, and its power generation efficiency was evaluated. First, an adhesive agent was prepared by dispersing, in an acrylic adhesive agent, approximately 5% by weight of a rare earth complex (particles of a complex such as a [Tb(bpy)2]Cl3 complex, a [Tb(terpy)2]Cl3 complex, and an [Eu(phen)2]Cl3 complex; each particle has a size of 5 μm to 10 μm) which produces luminescence in response to ultraviolet light. Then, PET films (each having a thickness of 200 μm) were adhered to both sides of an acrylic substrate (having a size of 1 m×1 m) via respective adhesive layers 4, each of which was prepared by the above adhesive agent. Each of the adhesive layers 4 was configured to have a thickness of 100 μm.

Then, solar cell elements 3, each of which had a light-receiving part having a width of 10 mm, were provided on four edge surfaces of the acrylic substrate. The acrylic materials all had a refractive index of 1.5. The solar cell module 10 thus prepared generated electric power of approximately 500 W when it is irradiated with sunlight. On the other hand, conventional solar cell modules, which were arranged all over a plane, generated electric power of approximately 145 W when they were irradiated with sunlight. Note that the conventional solar cell modules were solar cell modules each of which is to be directly irradiated with sunlight, unlike the solar cell module 10 of the present embodiment in which the solar cell elements 3 are to be irradiated with converged light.

Another solar cell module 10 was prepared as follows, and its power generation efficiency was evaluated. First, an adhesive agent was prepared by dispersing a fluorescent substance in an acrylic adhesive agent having a refractive index n(a)=1.50. Then, light-transmitting films 2, each of which was made of a polypropylene resin having a refractive index n(f)=1.49, were adhered to both sides of a glass substrate (light guide plate 1), which had a refractive index n(s)=1.54, via respective adhesive layers 4 each of which was made of the adhesive agent above prepared. The glass substrate was configured to have a size of 1 m×1 m and a thickness of 5 mm. Then, solar cell elements 3, each of which had a width of 5 mm, were provided on two side surfaces of the glass substrate to which two side surfaces the light-transmitting films 2 were not adhered. The another solar cell module 10 thus prepared generated electric power of approximately 90 W when the another solar cell module 10 was irradiated with sunlight. On the other hand, conventional solar cell modules, which were arranged all over a plane, generated electric power of approximately 35 W when the conventional solar cell modules were irradiated with sunlight.

According to the solar cell modules 10, the light-transmitting films 2 are thus adhered to the light guide plate 1 via the respective adhesive layers 4 in each of which the fluorescent substance is dispersed. It is therefore possible to repair or alter the solar cell module 10 only by replacing the adhesive layers 4 and the light-transmitting films 2 with another ones. Therefore, the solar cell module 10 of the present embodiment (i) has a drastically high degree of freedom for design and (ii) can be easily manufactured. Moreover, according to the present embodiment, the adhesive layer 4, in which the fluorescent substance is dispersed, is used instead of a conventional light guide plate in which a fluorescent substance is dispersed. Such an adhesive layer 4 can be manufactured at lower cost than the conventional light guide plate, and manufacturing cost of the solar cell module 10 can therefore be suppressed. Moreover, since a fluorescent substance is dispersed in the adhesive layer 4, it is easy to mix the adhesive layer 4 with the fluorescent substance. As such, it is easy to prepare the adhesive layer 4 which can serve as a fluorescent layer.

Moreover, according to the light guide plate 1 of the present embodiment, the solar cell elements 3 are provided on the edge surfaces perpendicular to the daylight surface. This allows the solar cell module 10 to achieve sufficient power generation efficiency in spite of a small area. It is therefore possible to manufacture the solar cell module 10 at low cost. In addition, the relation between the refractive index of the light guide plate 1 and the refractive index of the adhesive layer 4 is controlled in the present embodiment. This allows light, emitted from the fluorescent substance which has been excited by sunlight, to be efficiently guided in the light guide plate 1. The solar cell module 10 of the present embodiment, therefore, can be provided in a window frame of a building or of an automobile or can be provided on a roof. This makes it possible to provide a highly efficient solar photovoltaic system.

It is possible to express a solar cell module 10 of the present embodiment as follows. That is, the solar cell module 10 includes (i) a light guide plate 1, (ii) at least one fluorescent layer in which a fluorescent substance is dispersed, the at least one fluorescent layer being provided on respective at least one surface of the light guide plate 1, and each of the at least one fluorescent layer being made up of a light-transmitting film 2 and an adhesive layer 4, and (iii) a solar cell element 3 which is provided on another surface of the light guide plate 1, the another surface being perpendicular to the at least one surface.

### (Solar Photovoltaic Device)

A solar photovoltaic device of the present invention includes the solar cell module 10 above described. The solar photovoltaic device of the present invention can include, for example, a plurality of solar cell modules 10 and a storage battery which stores electric power supplied from each of the plurality of solar cell modules 10. The solar photovoltaic device of the present invention includes the solar cell module 10 and is therefore capable of efficiently converting solar energy into electric power at a location such as at a window or a roof of a building or at a window of an automobile.

### Embodiment 2

A solar cell module 10 of this Embodiment 2 is different from that of Embodiment 1 in that an infrared absorption agent is dispersed in an adhesive layer 4. In this Embodiment 2, a description will be merely given to configurations different from those of Embodiment 1, and descriptions regarding the other configurations are omitted.

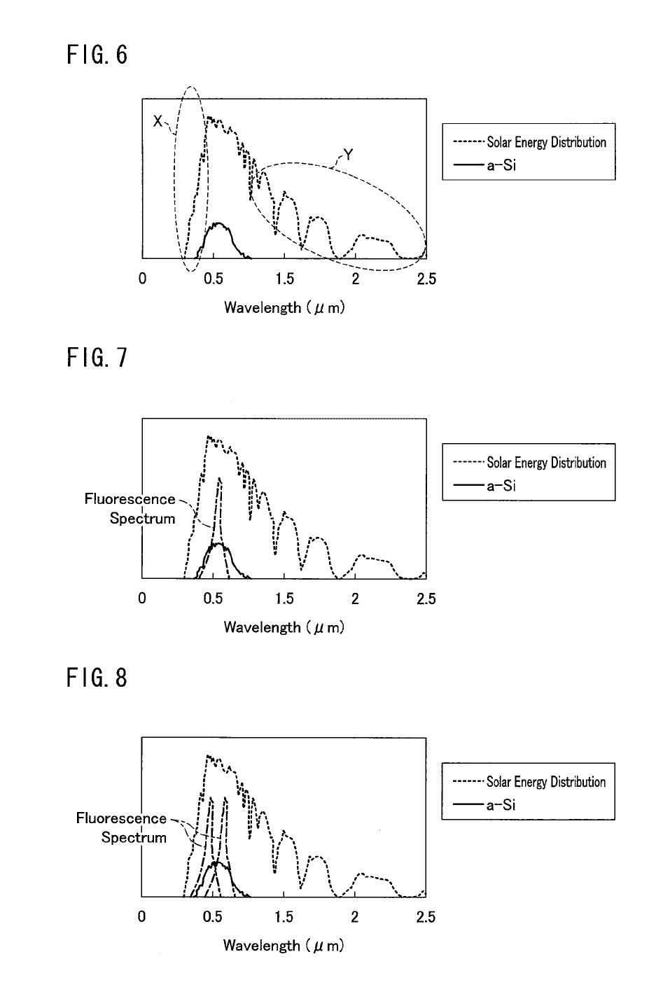

Aluminum nitride particles can be used as the infrared absorption agent which is to be dispersed in the adhesive layer 4 of the solar cell module 10 in accordance with the present embodiment. Note, however, that the infrared absorption agent is not limited to this. The infrared absorption agent, which is dispersed in the adhesive layer 4, absorbs infrared light, which has a wavelength falling within a region Y of a solar energy distribution illustrated in a graph of FIG. 6, so as to prevent the infrared light from passing through the infrared absorption agent.

It is preferable that the infrared absorption agent has a particle diameter of 1 μm to 100 μm. This allows infrared light to be efficiently absorbed. Moreover, it is preferable that a content of the infrared absorption agent in the adhesive layer 4 is 10% by weight or less. This makes it possible to prevent scattering of light in the light guide plate 1. Note that the infrared absorption agent can be dispersed in the light-transmitting film 2. Alternatively, the infrared absorption agent can be dispersed in both the light-transmitting film 2 and the adhesive layer 4. Note also that an infrared reflection agent, which reflects infrared ray so as to prevent the infrared ray from passing through, can be dispersed, instead of the infrared absorption agent, in the light-transmitting film 2 or in both the light-transmitting film 2 and the adhesive layer 4. Infrared absorption can occur in the light-transmitting film 2 or in the adhesive layer 4. As such, the following description will discuss, as an example, a case where a light-transmitting film 2 is employed).

A solar cell module 10 having a configuration illustrated in FIGS. 1 and 2 was prepared in a manner similar to that of Embodiment 1, except that aluminum nitride particles were dispersed in a light-transmitting film 2 by 1% by weight. The solar cell module 10 blocked, by approximately 80%, infrared light having a wavelength of approximately 800 μm. As such, in a case where the solar cell module 10 is provided in a window frame so as to be used as a windowpane, (i) photovoltaic power generation can be efficiently carried out and (ii) infrared rays, which increase an indoor temperature, can be effectively blocked.

Note that, according to the present embodiment, the infrared absorption agent is dispersed in the light-transmitting film 2 so as to block infrared rays passing through the solar cell module 10. Alternatively, a similar effect can be brought about by providing an infrared reflection layer(s) on at least one of surfaces of the light-transmitting film 2. In such a case, a layer such as a cholesteric liquid crystal layer or a dielectric multilayer film can be used as the infrared reflection layer.

### Embodiment 3

The following describes a solar cell module in accordance with Embodiment 3 of the present invention, with reference to FIG. 4. A solar cell module 40 of this Embodiment 3 is different from the solar cell module 10 of Embodiment 1 in that a light guide plate 1, to which both sides respective light-transmitting films 2 are adhered via respective adhesive layers 4, has a thickness, in its thickness direction, which thickness is thicker in center part than in end parts (see FIG. 4). In this Embodiment 3, a description will be merely given to configurations different from those of Embodiment 1, and descriptions regarding the other configurations are omitted.

According to the solar cell module 40, the light guide plate 1 (a daylight surface and opposed surface) has a shape which is thickened toward the end parts from its center part. The light guide plate 1 has a thickness, in the thickness direction, which thickness is continuously thickened toward the end parts from the center part. The edge parts of the light guide plate 1 are the thickest in the thickness direction. It is therefore possible to easily provide solar cell elements 3 on edge surfaces of the light guide plate 1.

A solar cell module 40 as illustrated in FIG. 4 was prepared for evaluation. First, an adhesive agent was prepared by dispersing a fluorescent substance in an acrylic adhesive agent having a refractive index n(a)=1.50. Subsequently, light-transmitting films 2, each of which was made of a cycloolefin polymer resin having a refractive index n(f)=1.50, were adhered to both sides of a polycarbonate substrate (light guide plate 1), which had a refractive index n(s)=1.59, via respective adhesive layers 4 made of the adhesive agent above prepared. The polycarbonate substrate (having a size of 1 m×1 m) was configured to (i) have a thickness, in the thickness direction, which thickness is continuously thickened toward the ends from the center part and (ii) have, in the thickness direction, a center thickness of 3 mm and an end thickness of 5 mm. Next, solar cell elements 3, each of which had a width of 5 mm, were provided on all edge surfaces (four edge surfaces) of the polycarbonate substrate to which edge surfaces the light-transmitting film 2 were not adhered. According to the configuration, the polycarbonate substrate had a thickness which continuously thickened toward the ends from the center part. It was therefore possible to easily provide the solar cell elements 3 on edge surfaces of the polycarbonate substrate.

### Embodiment 4

The following describes a solar cell module in accordance with Embodiment 4 of the present invention, with reference to FIG. 5. FIG. 5 is a cross-sectional view illustrating a solar cell module 50 of this Embodiment 4. The solar cell module 50 is different from the solar cell module 10 of Embodiment 1 in that the solar cell module 50 includes two light guide plates 1 which are adhered to each other via an adhesive layer 4 (see FIG. 5). In this Embodiment 4, a description will be merely given to configurations different from those of Embodiment 1, and descriptions regarding the other configurations are omitted. Note that the number of the light guide plates 1 is not limited to a particular one, provided that (i) each adhesive layer 4 is provided between corresponding adjacent ones of a plurality of light guide plates 1 and (ii) the corresponding adjacent ones of the plurality of light guide plates 1 are adhered to each other via the each adhesive layer 4.

According to the solar cell module 50, the adhesive layer 4 is sandwiched between the two light guide plates 1. The solar cell module 50 thus has a multiple glazing configuration. This allows (i) provision of a highly efficient solar photovoltaic system and (ii) the solar cell module 50 to be used as a windowpane which has (a) an excellent heat insulating property and (b) enhanced strength.

### Embodiment 5

The following describes a solar cell module in accordance with Embodiment 5 of the present invention, with reference to FIGS. 6 through 8. FIG. 6 is a graph illustrating a sensitivity distribution of a solar cell and a solar energy distribution. FIG. 7 is a graph illustrating a relation between (i) a fluorescence spectrum of a solar cell module and (ii) a sensitivity distribution of a solar cell and a solar energy distribution, in accordance with an embodiment of the present invention. FIG. 8 is a graph illustrating a relation between (i) a fluorescence spectrum of a solar cell module and (ii) a sensitivity distribution of a solar cell and a solar energy distribution, in accordance with an embodiment of the present invention.

A solar cell module of this Embodiment 5 is different from the solar cell module 10 of Embodiment 1 in that a fluorescent substance, having a maximum fluorescent wavelength substantially identical with a maximum sensitivity wavelength of a solar cell element 3, is contained in an adhesive layer 4. In this Embodiment 5, a description will be merely given to configurations different from those of Embodiment 1, and descriptions regarding the other configurations are omitted.

The fluorescent substance, which is contained in the adhesive layer 4 of the solar cell module in accordance with the present embodiment, has the maximum fluorescent wavelength substantially identical with the maximum sensitivity wavelength of the solar cell element 3. Here, solar energy is distributed in a wide range of wavelength so as to spread beyond a range of a sensitivity distribution of an amorphous silicon solar cell (a-Si) which is used as the solar cell element 3 (see FIG. 6). In view of the circumstances, a wavelength conversion is carried out, with the use of the fluorescent substance contained in the adhesive layer 4, so that the solar energy in a range X (see FIG. 6) is distributed within the range of the sensitivity distribution of the solar cell element 3.

Note that it is preferable that the maximum fluorescent wavelength of the fluorescent substance contained in the adhesive layer 4 substantially conforms to the maximum sensitivity wavelength of the solar cell element 3 (see the fluorescence spectrum shown in FIG. 7). This is because such a conformity of the wavelengths allows more efficient photoelectric conversion. According to the present embodiment, since the fluorescent substance, having the maximum fluorescent wavelength substantially identical with the maximum sensitivity wavelength of the solar cell element 3, is contained in the adhesive layer 4, it is possible to efficiently convert solar energy into electric energy.

In this specification, the phrase “fluorescent substance having the maximum fluorescent wavelength substantially identical with (or substantially conforms to) the maximum sensitivity wavelength of the solar cell element 3” indicates not only a case where the maximum fluorescent wavelength is completely identical with the maximum sensitivity wavelength, but also a case where (i) the fluorescence spectral distribution of the fluorescent substance and (ii) the sensitivity wavelength distribution of the solar cell element 3 partially overlap each other such that a peak of the fluorescence spectral distribution comes close to a peak of the sensitivity wavelength distribution. As such, it is possible to express as “a peak of the fluorescence spectral distribution is identical with a peak of the sensitivity wavelength distribution” even in a case where (i) the fluorescence spectral distribution of the fluorescent substance and (ii) the sensitivity wavelength distribution of the solar cell element 3 partially overlap each other such that a peak of the fluorescence spectral distribution comes close to a peak of the sensitivity wavelength distribution.

A solar cell module was prepared in a manner similar to that of Embodiment 1, except that a sialon fluorescent substance (Ca-α-SiAlON:Eu) was contained in an adhesive layer 4. First, an adhesive agent was prepared by dispersing the sialon fluorescent substance (Ca-α-SiAlON:Eu) in an acrylic adhesive agent having a refractive index n(a)=1.50. Subsequently, light-transmitting films 2, each of which was made of an acrylic resin having a refractive index n(f)=1.50, were adhered to both sides of a polycarbonate substrate (light guide plate 1), which had a refractive index n(s)=1.59, via respective adhesive layers 4 prepared by the above adhesive agent. The polycarbonate substrate was configured to have a thickness of 5 mm and a plane area size of 1 m×1 m. Further, solar cell elements 3, each of which had a width of 5 mm, were provided on edge surfaces (four surfaces) of the polycarbonate substrate. An a-Si solar cell was used as each of the solar cell elements. Solar energy could be efficiently converted into electric energy, because the a-Si solar cell had a maximum sensitivity wavelength substantially identical with a maximum fluorescent wavelength of the sialon fluorescent substance (see FIG. 7).

Alternatively, an adhesive layer 4 can be prepared by a plurality of stacked adhesion layers in which fluorescent substances having respective different absorption wavelengths are contained. In each of the plurality of stacked adhesion layers, a corresponding fluorescent substance having a corresponding maximum fluorescent wavelength substantially identical with the maximum sensitivity wavelength of the solar cell element 3 (see FIG. 8) is contained. This allows various frequency ranges of light to be converted into respective wavelengths falling within a sensitivity range of the solar cell element 3. This ultimately allows an increase in power generation efficiency.

It is possible to use, as the fluorescent substances for adhesion layers which have the respective different absorption wavelengths, Lumogen F Violet 570 (maximum absorption wavelength: 378 nm, maximum emission wavelength: 413 nm), Lumogen F Yellow 083 (maximum absorption wavelength: 476 nm, maximum emission wavelength: 490 nm), Lumogen F Orange 240 (maximum absorption wavelength: 524 nm, maximum emission wavelength: 539 nm), and Lumogen F Red 305 (maximum absorption wavelength: 578 nm, maximum emission wavelength: 613 nm) (all of these are manufactured by BASF) in combination.

Alternatively, it is also possible to convert various frequency ranges of light into respective wavelengths falling within a sensitivity range of the solar cell element 3, by adhering (i) one of two adhesive layers 4, in which fluorescent substances having respective different absorption wavelengths are contained, to a daylight surface of the light guide plate 1 and (ii) the other of the two adhesive layers 4 to an opposed surface of the light guide plate 1. This allows an increase in power generation efficiency.

### Embodiment 6

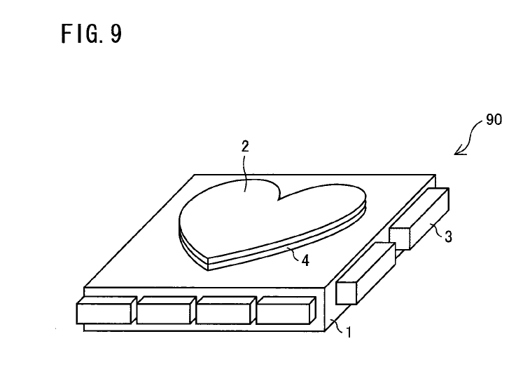

The following describes a solar cell module in accordance with Embodiment 6 of the present invention, with reference to FIG. 9. FIG. 9 is a perspective view illustrating a solar cell module 90 in accordance with this Embodiment 6 of the present invention. The solar cell module 90 is different from the solar cell module 10 of Embodiment 1 in that a light-transmitting film 2 is partially adhered to a daylight surface of a light guide plate 1 via an adhesive layer 4. In this Embodiment 6, a description will be merely given to configurations different from those of Embodiment 1, and descriptions regarding the other configurations are omitted.

According to the solar cell module 90, the light-transmitting film 2 is a heart-shaped film which is adhered to the daylight surface of the light guide plate 1 via the adhesive layer 4 which similarly has a shape of heart. That is, according to the solar cell module 90, the light-transmitting film 2 and the adhesive layer 4, in which a fluorescent substance is contained, are adhered to only part of the daylight surface of the light guide plate 1, instead of being adhered to the entire daylight surface. In a case where the solar cell module 90 is used as, for example, a windowpane, it is possible to improve a design of the windowpane by configuring the light-transmitting film 2 and the adhesive layer 4 to have a desired shape. Moreover, since the adhesive layer 4 is not adhered to the entire daylight surface of the light guide plate 1, light, which is guided in the light guide plate 1, is less likely to collide with the fluorescent substance, and therefore the light can be efficiently guided. This allows an improvement in power generation efficiency.

A solar cell module 90 as shown in FIG. 9 was prepared as follows. First, a heart-shaped adhesive layer 4 was prepared by dispersing a fluorescent substance in an acrylic adhesive agent having a refractive index n(a)=1.50. Subsequently, a light-transmitting film 2, which was made of a polypropylene resin having a refractive index n(f)=1.49, was adhered to a top surface of a glass substrate (light guide plate 1) having a refractive index n(s)=1.54 via the adhesive layer 4 above prepared. The glass substrate was configured to have a thickness of 5 mm and a plane area size of 1 m×1 m. Then, solar cell elements 3, each of which had a width of 5 mm, were provided on edge surfaces (four edge surfaces) of the glass substrate which are perpendicular to the surface to which the light-transmitting film 2 was adhered via the adhesive layer 2. According to the solar cell module 90 thus prepared, it was possible to realize a solar photovoltaic system window which excelled in design. Further, it became possible to efficiently generate electric power, based on the fact that, since the adhesive layer 4 was not adhered to the entire daylight surface, the light, which was being guided in the glass substrate, was less likely to collide with the fluorescent substance.

The present invention is not limited to the embodiments, but can be altered by a skilled person in the art within the scope of the claims. An embodiment derived from a proper combination of technical means disclosed in respective different embodiments is also encompassed in the technical scope of the present invention.

It is preferable that the solar cell module of the present invention further includes at least one light-transmitting film which is adhered to the at least one light guide plate via the respective at least one adhesive layer. According to the configuration, the at least one light-transmitting film is adhered to the at least one light guide plate via the respective at least one adhesive layer in which the fluorescent substance is dispersed. This allows light, which has entered the at least one adhesive layer via the at least one light-transmitting film, to be guided toward the solar cell element. With the configuration, it is possible to easily produce the solar cell module, because the adhesive layer can be prepared by such an easy manner that the fluorescent substance is mixed with the adhesive agent.

According to the solar cell module of the present invention, it is preferable that the at least one light guide plate includes a plurality of light guide plates; and each adhesive layer is provided between corresponding adjacent ones of the plurality of light guide plates, the corresponding adjacent ones of the plurality of light guide plates being adhered to each other via the each adhesive layer.

According to the configuration, the each adhesive layer is sandwiched between the corresponding adjacent ones of the plurality of light guide plates. The solar cell module thus has a multiple glazing configuration, and therefore a highly efficient solar photovoltaic system can be provided. Moreover, the solar cell module is applicable to, for example, a windowpane having (i) an excellent heat insulating property and (ii) enhanced strength.

According to the solar cell module of the present invention, it is preferable that the at least one light guide plate has a refractive index which is equal to or higher than that of the at least one adhesive layer. With the configuration, light, which has entered the at least one adhesive layer, can be efficiently guided toward the at least one light guide plate without being subjected to total reflection at an interface between the adhesive layer and the light guide plate. This allows sunlight, which has entered the solar cell module 10, to be efficiently converged onto the solar cell element, and therefore power generation efficiency is improved.

According to the solar cell module of the present invention, it is preferable that the at least one surface is a first surface and a second surface which face each other and to each of which a corresponding adhesive layer is adhered. This allows an improvement in sunlight conversion efficiency.

According to the solar cell module of the present invention, it is preferable that an infrared absorption agent or an infrared reflection agent is further dispersed in the at least one adhesive layer. With the configuration, in a case where the solar cell module is provided in a window frame so as to be used as a windowpane, (i) photovoltaic power generation can be efficiently carried out and (ii) an increase in indoor temperature can be suppressed by blocking infrared light.

According to the solar cell module of the present invention, it is preferable that the at least one light guide plate has a thickness, in a direction perpendicular to the at least one surface, which thickness is thickened toward its end parts from its center part. This allows the solar cell element to be easily provided on the at least one light guide plate.

According to the solar cell module of the present invention, it is preferable that the fluorescent substance has a maximum fluorescent wavelength which is substantially identical with a maximum sensitivity wavelength of the solar cell element. This makes it possible to convert a wavelength of light, which wavelength does not fall within the sensitivity range of the solar cell element, into a wavelength falling within the wavelength range. It is therefore possible to efficiently convert solar energy into electric energy.

According to the solar cell module of the present invention, it is preferable that the at least one adhesive layer is made up of a plurality of stacked adhesion layers in which fluorescent substances having respective different absorption wavelengths are dispersed; and the fluorescent substances which are dispersed in the respective plurality of stacked adhesion layers have respective maximum fluorescent wavelengths each of which is substantially identical with the maximum sensitivity wavelength of the solar cell element. With the configuration, various frequency ranges of light can be converted into respective wavelengths falling within the sensitivity range of the solar cell element. This ultimately allows an increase in power generation efficiency.

According to the solar cell module of the present invention, it is preferable that the at least one adhesive layer is provided on at least part of the at least one surface. With the configuration, it is possible to partially provide the at least one adhesive layer on the at least one light guide plate by desirably patterning the at least one adhesive layer, instead of providing the at least one adhesive layer on an entire surface of the at least one light guide plate. This allows the solar cell module to excel in design. Further, the configuration of the solar cell module makes it possible to reduce provability of light, which is being guided in the at least one light guide plate, colliding with the fluorescent substance, and accordingly the light can be efficiently guided in the at least one light guide plate. Consequently, power generation efficiency is improved.

According to the solar cell module of the present invention, it is preferable that the at least one adhesive layer has a refractive index which (i) is equal to or lower than that of the at least one light-transmitting film and (ii) is equal to or lower than that of the at least one light guide plate. With the configuration, light, which has entered the solar cell module, can be efficiently guided in the at least one light guide plate without being subjected to total reflection at an interface between the adhesive layer and the at least one light guide plate. Further, it is possible to suppress reflection of sunlight caused by a boundary surface between the adhesive layer and the light-transmitting film, and therefore the sunlight can be efficiently guided in the at least one light guide plate. This allows the sunlight, which has entered the solar cell module, to be efficiently converged onto the solar cell element, and therefore power generation efficiency is improved.

### INDUSTRIAL APPLICABILITY

The present invention provides a solar cell module which has a higher degree of freedom for design and can easily be manufactured at low cost. Such a solar cell module can be suitably used as a solar photovoltaic system which is provided at a window of a building or of an automobile or is provided on a roof of a building.

### REFERENCE SIGNS LIST

1: Light guide plate
2: Light-transmitting film
3: Solar cell element
4: Adhesive layer
10: Solar cell module

1. A solar cell module comprising:
at least one light guide plate;
at least one adhesive layer in each of which a fluorescent substance is dispersed, the at least one adhesive layer being provided on respective at least one surface of the at least one light guide plate; and
a solar cell element which is provided on another surface of the at least one light guide plate, the another surface being perpendicular to the at least one surface.

2. A solar cell module as set forth in claim 1, further comprising:
at least one light-transmitting film which is adhered to the at least one light guide plate via the respective at least one adhesive layer.

3. The solar cell module as set forth in claim 1, wherein:
the at least one light guide plate includes a plurality of light guide plates; and
each adhesive layer is provided between corresponding adjacent ones of the plurality of light guide plates, the corresponding adjacent ones of the plurality of light guide plates being adhered to each other via the each adhesive layer.

4. The solar cell module as set forth in claim 1, wherein:
the at least one light guide plate has a refractive index which is equal to or higher than that of the at least one adhesive layer.

5. The solar cell module as set forth in claim 1, wherein:
the at least one surface is a first surface and a second surface which face each other and to each of which a corresponding adhesive layer is adhered.

6. The solar cell module as set forth in claim 1, wherein:
an infrared absorption agent or an infrared reflection agent is further dispersed in the at least one adhesive layer.

7. The solar cell module as set forth in claim 1, wherein:
the at least one light guide plate has a thickness, in a direction perpendicular to the at least one surface, which thickness is thickened toward its end parts from its center part.

8. The solar cell module as set forth in claim 1, wherein:
the fluorescent substance has a maximum fluorescent wavelength which is substantially identical with a maximum sensitivity wavelength of the solar cell element.

9. The solar cell module as set forth in claim 1, wherein:
the at least one adhesive layer is made up of a plurality of stacked adhesion layers in which fluorescent substances having respective different absorption wavelengths are dispersed; and
the fluorescent substances which are dispersed in the respective plurality of stacked adhesion layers have respective maximum fluorescent wavelengths each of which is substantially identical with the maximum sensitivity wavelength of the solar cell element.

10. The solar cell module as set forth in claim 1, wherein:
the at least one adhesive layer is provided on at least part of the at least one surface.

11. The solar cell module as set forth in claim 2, wherein:
the at least one adhesive layer has a refractive index which (i) is equal to or lower than that of the at least one light-transmitting film and (ii) is equal to or lower than that of the at least one light guide plate.

12. A solar photovoltaic device comprising a solar cell module recited in claim 1.
